(19) United States
(12) Patent Application Publication
(10) Pub. No.: US 2026/0299705 A1
(43) Pub. Date: Oct. 1, 2026

(54) DETECTION METHOD AND DETECTION DEVICE FOR KEYBOARD KEY AND COMPUTER STORAGE MEDIUM

(71) Applicant: SHENZHEN TIMELINK TECHNOLOGY CO., LTD., Shenzhen (CN)

(72) Inventors: Weishan CHEN, Shenzhen (CN); Huaqin DENG, Shenzhen (CN); Jian LV, Shenzhen (CN); Furong LI, Shenzhen (CN)

(73) Assignee: SHENZHEN TIMELINK TECHNOLOGY CO., LTD., Shenzhen (CN)

(21) Appl. No.: 19/323,700

(22) Filed: Sep. 9, 2025

(30) Foreign Application Priority Data
Mar. 31, 2025 (CN) 202510392618.5

(51) Int. Cl. G06F 3/02

(52) U.S. Cl. CPC G06F 3/0202

(57) ABSTRACT

A detection method for a keyboard key includes: detecting a signal strength value of an infrared light received by the infrared receiving tube; in response to that the signal strength value is lower than a preset threshold, identifying blocked infrared lights and generating a blocked light path combination; determining a triggered target key based on the blocked light path combination; and calculating a travel depth of the target key based on a signal strength change value of the blocked light path combination. This method forms an infrared light network through an infrared emitting tube and an infrared receiving tube, and a light-blocking cylinder is provided at the bottom of the key. The method uses the blocked light path combination formed when the light-blocking cylinder intrudes the infrared light network to determine the triggered target key.

### CROSS-REFERENCE TO RELATED APPLICATIONS

The present application claims priority to Chinese Patent Application No. 202510392618.5, filed on Mar. 31, 2025, the entire contents of which are incorporated herein by reference.

### TECHNICAL FIELD

The present application relates to the technical field of input device, and in particular to a detection method and a detection device for a keyboard key, and a computer storage medium.

### BACKGROUND

Current keyboard key detection is mainly implemented using mechanical switches, thin-film circuits, or infrared diodes. However, these methods only trigger a signal when a key is fully pressed and only provide a binary state of “pressed” or “not pressed”. They are unable to detect changes in key depth when the key is pressed. Using optical detection or pressure sensing to detect key depth requires installing a separate photoelectric element beneath each key, resulting in a linear increase in the number of components required. Furthermore, because the photoelectric elements are installed directly beneath the moving parts of the key, mechanical shock and continuous vibration from the key during daily use can directly affect these elements, potentially causing performance degradation or even failure, thereby shortening the service life of the key.

### SUMMARY

The main objective of the present application is to provide a detection method and a detection device for a keyboard key, and a computer storage medium, aiming to address the technical problems of high costs for detecting the depth of the keyboard key.

To achieve the above purpose, the present application provides a detection method for a keyboard key, applied to an infrared keyboard. The infrared keyboard includes: a keyboard operation area, at least one group of opposite sides of the keyboard operation area is provided with an infrared array including a plurality of groups of infrared emitting tubes and infrared receiving tubes opposite to the infrared emitting tubes, and an infrared light network composed of multiple intersecting infrared lights is formed at the keyboard operation area; a key is provided at the keyboard operation area, a light-blocking cylinder configured to move vertically with a movement of the key is fixedly provided at a bottom of the key, and the light-blocking cylinder is initially positioned at a preset distance above the infrared light network; and
the detection method for the keyboard key includes:
detecting a signal strength value of an infrared light received by the infrared receiving tube;
in response to that the signal strength value is lower than a preset threshold, identifying blocked infrared lights and generating a blocked light path combination;
determining a triggered target key based on the blocked light path combination; and
calculating a travel depth of the target key based on a signal strength change value of the blocked light path combination.

In an embodiment, the step of in response to that the signal strength value is lower than the preset threshold, identifying blocked infrared lights and generating the blocked light path combination includes:
obtaining signal strength values of all current infrared lights, filtering out infrared lights with signal strength values lower than the preset threshold to obtain the blocked infrared lights;
determining serial numbers of the blocked infrared lights based on a preset infrared light numbering rule; and
combining the serial numbers of the blocked infrared lights in a same time window to form the blocked light path combination.

In an embodiment, the step of determining the triggered target key based on the blocked light path combination includes:
searching for a preset key mapping table storing corresponding relationships between each key and the blocked light path combination; and
matching the blocked light path combination with the preset key mapping table to determine the triggered target key.

In an embodiment, the step of matching the blocked light path combination with the key mapping table to determine the triggered target key includes:
in response to that there is no single target key that fully matches the blocked light path combination in the key mapping table, searching for all candidate keys that partially match the blocked light path combination in the key mapping table;
based on a preset blocked light path combination corresponding to the candidate keys, determining whether there exists a key combination that fully matches the blocked light path combination after merging with the preset blocked light path combination corresponding to the key combination; and
in response to that there exists the key combination that fully matches the blocked light path combination after merging with the preset blocked light path combination corresponding to the key combination, determining the key combination as the triggered target key.

In an embodiment, the step of in response to that there exists the key combination that fully matches the blocked light path combination after merging with the preset blocked light path combination corresponding to the key combination, determining the key combination as the triggered target key includes:
calculating a blocking priority of each key in the key combination based on an amount of the blocked infrared lights in the preset blocked light path combination corresponding to each key in the key combination; and
determining a triggering order of each key in the key combination in a descending order of the blocking priority;
the blocking priority is calculated as a ratio of an actual amount of the blocked infrared lights in the preset blocked light path combination corresponding to the key to a total amount of infrared lights in the preset blocked light path combination.

In an embodiment, the step of calculating the travel depth of the target key based on the signal strength change value of the blocked light path combination includes:
obtaining an initial signal strength value and a current signal strength value of each infrared light in the blocked light path combination;
calculating a signal strength change value of each infrared light, the signal strength change value is a difference between the initial signal strength value and the current signal strength value; and
determining the travel depth of the target key based on a mapping relationship between the signal strength change value and a preset travel depth.

In an embodiment, after calculating the travel depth of the target key based on the signal strength change value of the blocked light path combination, the method further includes:
in response to that the travel depth of the target key is detected to reach a preset trigger threshold, generating a corresponding key trigger signal; and
adjusting a trigger sensitivity of the key trigger signal based on a change rate of the travel depth;
the trigger sensitivity is adjusted by:
lowering the trigger threshold in response to that the change rate of the travel depth is detected to exceed a first rate threshold; and
raising the trigger threshold in response to that the change rate of the travel depth is detected to be lower than a second rate threshold.

In an embodiment, after the step of in response to that the travel depth of the target key is detected to reach the preset trigger threshold, generating the corresponding key trigger signal, the method further includes:
detecting changes in infrared light signal strength in an adjacent area of the target key;
in response to that a concomitant signal change exists in the adjacent area of the target key, determining whether a false touch operation occurs; and
in response to that the false touch operation occurs, suppressing signal output in the adjacent area of the target key.

The present application also provides a detection device for keyboard key, including: a memory, a processor, and a computer program stored in the memory and executable on the processor, the computer program is configured to implement steps of the detection method for keyboard key.

The present application also provides a non-transitory computer-readable storage medium, storing a computer program configured to implement steps of the detection method for keyboard key when executed by a processor.

The present application discloses a detection method for keyboard key that detects the signal strength of infrared light received by an infrared receiving tube. When the signal strength is below a preset threshold, the method identifies the blocked infrared lights and generates a blocked light path combination. Based on the blocked light path combination, the method determines the triggered target key. Finally, the method calculates the travel depth of the target key based on the signal strength change value of the blocked light path combination. This method forms an infrared light network through an infrared emitting tube and an infrared receiving tube, and a light-blocking cylinder is provided at the bottom of the key. The method uses the blocked light path combination formed when the light-blocking cylinder intrudes the infrared light network to determine the triggered target key. Furthermore, the method accurately detects the key press depth based on the signal strength change value of the blocked light path combination, meeting the personalized key requirements of different users.

### BRIEF DESCRIPTION OF THE DRAWINGS

FIG. 1 is a schematic flow chart of a detection method for keyboard key according to an embodiment of the present application.

FIG. 2A is a schematic layout diagram of an infrared emitting tube and an infrared receiving tube according to an embodiment of the present application.

FIG. 2B is a schematic diagram of an infrared light network according to an embodiment of the present application.

FIG. 3 is a schematic flow chart of the detection method for keyboard key according to an embodiment of the present application.

FIG. 4 is a schematic flow chart of the detection method for keyboard key according to an embodiment of the present application.

FIG. 5A is a schematic diagram of a blocked infrared light network when one key is pressed according to an embodiment of the present application.

FIG. 5B is a schematic diagram of the blocked infrared light network when two keys are pressed according to an embodiment of the present application.

FIG. 6 is a schematic flow chart of the detection method for keyboard key according to an embodiment of the present application.

FIG. 7 is a schematic flow chart of the detection method for keyboard key according to an embodiment of the present application.

FIG. 8 is a schematic structural diagram of a detection device for the keyboard key according to an embodiment of the present application.

The realization of the objective, functional characteristics, and advantages of the present application are further described with reference to the accompanying drawings.

### DETAILED DESCRIPTION OF THE EMBODIMENTS

It should be understood that specific embodiments described herein are only intended to explain the present application and are not intended to limit the present application.

Current keyboard key detection is mainly implemented using mechanical switches, thin-film circuits, or infrared diodes. However, these methods only trigger a signal when a key is fully pressed and only provide a binary state of “pressed” or “not pressed”. They are unable to detect changes in key depth when the key is pressed. Using optical detection or pressure sensing to detect key depth requires installing a separate photoelectric element beneath each key, resulting in a linear increase in the number of components required. Furthermore, because the photoelectric elements are installed directly beneath the moving parts of the key, mechanical shock and continuous vibration from the key during daily use can directly affect these elements, potentially causing performance degradation or even failure, thereby shortening the service life of the key.

To address the aforementioned shortcomings in related art, embodiments of the present application provide a detection method for keyboard key. This method detects the signal strength of the infrared light received by an infrared receiving tube. When the signal strength is below a preset threshold, the method identifies the blocked infrared lights and generates a blocked light path combination. Based on the blocked light path combination, the method determines the triggered target key. Finally, the method calculates the travel depth of the target key based on the signal strength change value of the blocked light path combination. This method forms an infrared light network through the keyboard with infrared emitting tubes and infrared receiving tubes, and a light-blocking cylinder is provided at the bottom of the key. The method utilizes the blocked light path combination formed when the light-blocking cylinder intrudes the infrared light network to determine the triggered target key. Furthermore, the method accurately detects the key press depth based on the signal strength change value of the blocked light path combination, meeting the personalized key requirements of different users.

It should be noted that the implementation of this embodiment can be a detection system for keyboard key, or it can be an input device with infrared signal acquisition, data processing, network communication, and program execution functions, such as a keyboard or game controller, or a detection device for keyboard key capable of performing the aforementioned functions. This embodiment and the following embodiments are described below using a detection system for keyboard key as an example (hereinafter referred to as the “system”). The detection system for keyboard key can be integrated into the keyboard itself or used as an independent external process unit, interacting with the keyboard optical sensor module through wired or wireless communication. In actual applications, the specific implementation of the detection system for keyboard key can be adapted based on the product form and functional requirements, but should always include the core technical features described in the present application.

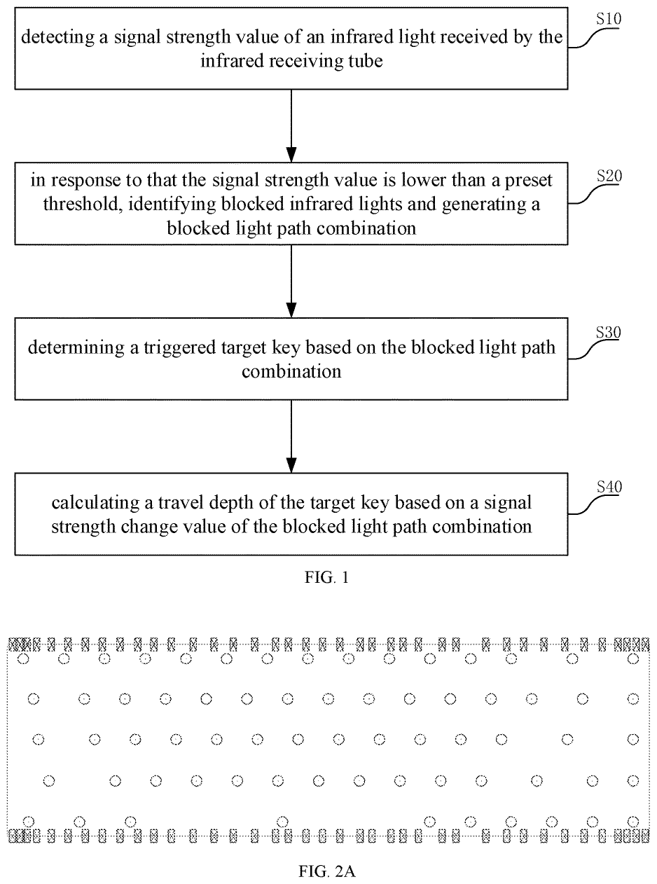

The detection method for keyboard key provided in the present application is applied to an infrared keyboard. The infrared keyboard includes a keyboard operation area. At least one group of opposite sides of the keyboard operation area is provided with an infrared array. The infrared array includes multiple groups of infrared emitting tubes and infrared receiving tubes opposite to the infrared emitting tubes. An infrared light network composed of multiple intersecting infrared lights is formed at the keyboard operation area. The keyboard operation area also includes a key. A light-blocking cylinder is fixedly provided at the bottom of the key and is vertically movable with the movement of the key. In an initial state, the light-blocking cylinder is positioned at a preset distance above the infrared light network. Referring to FIG. 1, the method includes steps S10 to S40.

Step S10: detecting a signal strength value of an infrared light received by the infrared receiving tube.

In this embodiment, the infrared array is arranged along at least one group of opposing edges around the keyboard operation area, such as the top and bottom edges and/or the left and right edges. The infrared array includes multiple groups of infrared emitting tubes and infrared receiving tubes. The multiple groups of infrared emitting tubes and infrared receiving tubes are provided with unequal spacing, allowing the spacing of the infrared emitting tubes and infrared receiving tubes to be adjusted based on the density of keys in different areas. This adaptive arrangement reduces the number of components while ensuring the detection accuracy of the key, thereby optimizing hardware costs.

The infrared light network is formed within the keyboard operation area, consisting of multiple intersecting infrared lights. The density of the infrared light network is determined by the spacing between the infrared emitting tubes and infrared receiving tubes. Typically, the spacing between adjacent infrared light must be less than half of the minimum key size to ensure the resolution of the key detection. Each infrared emitting tube emits infrared light at a specific radiation angle. Only infrared receiving tubes within this radiation angle range can effectively receive the infrared light emitted by the infrared emitting tube. The radiation angle of each infrared emitting tube can be different, and the angle range of the radiation angle can also be set according to actual needs.

It should be emphasized that regardless of the spacing of the infrared emitting tubes and infrared receiving tubes, or the radiation angle of the infrared emitting tubes, the detection logic in this embodiment is determined based on the change of the signal strength. These spacing and radiation angles are not specified in this embodiment.

In this embodiment, the non-uniform arrangement is to improve the detection accuracy of the key. By arranging the non-uniform spacing at opposite edges of the infrared emitting tubes and infrared receiving tubes, even if two keys are close together, they will form different light path combinations when blocking the infrared light, enabling the system to distinguish between different key actions.

After the infrared emitting tubes emit infrared light, when no key is operated, the infrared receiving tubes receive infrared light signals with stable signal strength. The infrared receiving tubes are devices that convert received infrared light signals into electrical signals, and the strength of the output electrical signals is related to the strength of the received infrared light. Detecting the infrared light signal strength value received by the infrared receiving tube involves quantifying the electrical signal received by the infrared receiving tube, thereby obtaining a specific numerical value to represent the strength of the current infrared light. A change in the signal strength value received by the infrared receiving tube indicates a key action. Specifically, when a user presses a key, the light-blocking cylinder attached to the bottom of the key moves downward, entering the infrared light network path and partially or completely blocking the corresponding infrared light. This blocking significantly reduces the signal strength detected by the infrared receiving tube in the blocked light path.

In this embodiment, the signal strength value output by each infrared receiving tube is acquired in real time through a high-speed analog-to-digital converter. During the design phase of the keyboard, the system predetermines the initial signal strength of each infrared light. For example, the signal strength value of the infrared light is in a range of 0 to 100, with the signal strength at full blocking being 0 and the signal strength at no blocking being 100. As the keyboard key is pressed, the signal strength gradually changes from 100 to 0, thereby determining of the target key and the purpose of the travel depth of the target key.

In an embodiment, the bottom of the light-blocking cylinder is conical or hemispherical, so that only the tip of the light-blocking cylinder blocks a small amount of the light path during downward movement. As the key is pressed deeper, the thicker portion of the light-blocking cylinder intrudes into the infrared light network and blocks more of the light path.

In an embodiment, the length of the light-blocking cylinder is greater than the maximum travel distance of the key. Specifically, the length of the light-blocking cylinder includes three parameters: the first parameter is the preset distance between the bottom of the light-blocking cylinder and the infrared light network when the key is not pressed; the second parameter is the maximum travel distance of the key from its initial state to the fully pressed state; and the third parameter is the distance buffer margin, which is used to prevent mechanical components from colliding at extreme positions. Therefore, the length of the light-blocking cylinder is equal to a sum of the preset distance from the infrared light network, the maximum travel distance of the key and the distance buffer margin. The preset distance and the distance buffer margin can be set based on actual scenarios and are not limited in this embodiment.

Step S20: in response to that the signal strength value is lower than a preset threshold, identifying blocked infrared lights and generating a blocked light path combination.

The preset threshold is a reference value set based on the signal strength value received by the infrared receiving tube when the key is not operated. When the key is pressed, the key partially blocks the infrared light, decreasing the signal strength received by the infrared receiving tube.

To accurately distinguish and locate different infrared lights, the corresponding infrared light is determined based on the arrangement of the infrared emitting tubes and infrared receiving tubes. For example, a unique serial number is assigned to each infrared light in a left-to-right and top-to-bottom order. The infrared light position is then associated with the corresponding serial number to create a serial number mapping table of the infrared light.

It can be understood that when the infrared emitting tubes and the infrared receiving tubes are installed at the keyboard, the physical positional relationship of which is fixed and established. Furthermore, since the radiation angle range of each infrared emitting tube is preset during the design phase of the hardware, the system assigns and stores a unique serial number to each infrared light during initialization based on the spatial relationship between each infrared emitting tube and its corresponding infrared receiving tube. This ensures that each infrared light is uniquely identified within the system, providing reliable reference data for subsequent recognition and location determination of the key.

In an embodiment, from left to right, the infrared light formed by the first infrared emitting tube E1 and the first infrared receiving tube R1 is marked as 1; and the infrared light formed by the first infrared emitting tube E1 and the second infrared receiving tube R2 is marked as 2.

In this embodiment, there are multiple groups of infrared emitting tubes and infrared receiving tubes forming different light paths in the keyboard operation area. When the detected signal strength value is lower than the preset threshold, it can be determined that the infrared light is blocked. Then, according to the serial number mapping table of the infrared light, the serial numbers corresponding to these blocked infrared lights are quickly queried and determined, and the serial numbers of these blocked infrared lights are integrated to generate the blocked light path combination.

Furthermore, when the key is pressed, the light-blocking cylinder moves downward in the vertical direction and invades the plane of the infrared light network. During this process, the movement of the light-blocking cylinder is divided into three stages:
initial contact stage: the edge of the light-blocking cylinder contacts the infrared light network for the first time, and the signal strength received by the infrared receiving tube decreases for the first time, indicating that the key pressing begins;
dynamic blocking stage: as the pressing depth of the key increases, the light-blocking cylinder will simultaneously block multiple cross-arranged infrared lights because the diameter of the light-blocking cylinder is larger than the spacing of adjacent light paths; and
stable judgment stage: when the key pressing reaches a certain depth, it is determined as a valid press if any of the following conditions are met:
a. the pressing speed slows down and the signal strength change rate drops to the range of the preset signal strength change value, for example, the signal strength change rate drops to 3-8%/ms;
b. there are no new blocked light paths within the preset time range, for example, there are no new blocked light paths within 2.5-3.5 ms;
c. the cumulative number of blocked light paths reaches the preset light path threshold to adapt to different pressing habits; and
d. the light-blocking cylinder reaches the maximum travel distance of the key.

In this embodiment, the system scans the infrared array to detect the blocked infrared lights in real time, recording the serial numbers of the blocked infrared lights, and thereby determining the corresponding blocked light path combination for the current key operation.

Step S30: determining a triggered target key based on the blocked light path combination.

In this embodiment, since the key positions at the keyboard are fixed, the system can pre-establish a mapping relationship table between keys and blocked light path combinations, that is, each key is pre-associated with a specific blocked light path combination. Specifically, after determining the serial number of each infrared light in advance based on the arrangement of the infrared emitting tubes and infrared receiving tubes, the system records the serial number of the blocked infrared lights in the infrared light network when each key is pressed by pressing the keyboard keys one by one. The serial numbers of the blocked infrared lights corresponding to all keys are then recorded and stored in a virtual table, which is used to store the corresponding relationship of the serial numbers of the blocked infrared lights and the key.

When a specific blocked light path combination is detected, the system matches it with the preset blocked light path combination in the virtual table. This allows the system to reversely determine the triggered target key.

Step S40: calculating a travel depth of the target key based on a signal strength change value of the blocked light path combination.

The travel depth of the key refers to the displacement of the key when it is pressed and can be used to evaluate the tactile feel of the key. In this embodiment, the travel depth of the target key is calculated by detecting the signal strength change value of the blocked light path combination. When the key is pressed, the blocking degree of the light-blocking cylinder at the bottom of the key to the infrared light varies with the displacement of the key, resulting in changes in signal strength. By analyzing the change of the signal strength, a relationship model between the signal strength change value and the travel depth of the key can be established, thereby calculating the travel depth of the target key.

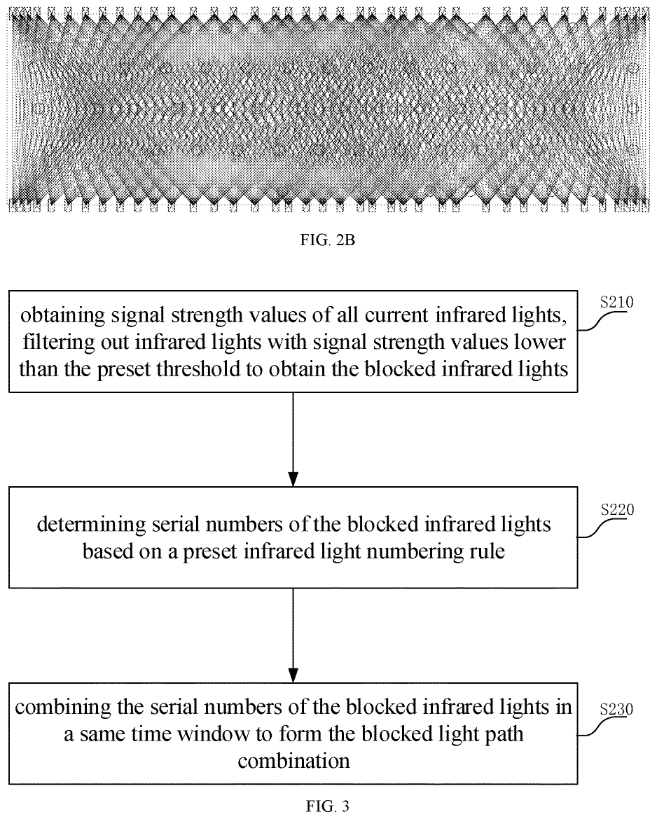

In order to realize the implementation process of the detection method for keyboard key, please refer to FIG. 2A. FIG. 2A provides a schematic layout diagram of the infrared emitting tubes and infrared receiving tubes.

Specifically, multiple groups of infrared emitting tubes and infrared receiving tubes are provided at the upper and lower sides of the edge of the keyboard operating area. Each of infrared emitting tubes is opposite to each of the infrared receiving tubes. The infrared emitting tubes and infrared receiving tubes are provided with uneven spacing, and the spacing between adjacent infrared emitting tubes can be adjusted according to the size of the keyboard and the layout of the key.

In order to realize the implementation process of the detection method for keyboard key in this embodiment, please refer to FIG. 2B. FIG. 2B provides a schematic diagram of the infrared light network.

Specifically, multiple groups of infrared emitting tubes and infrared receiving tubes are provided at the upper and lower sides of the edge of the keyboard operating area. Each of the infrared emitting tubes is opposite each of the infrared receiving tubes, generating multiple intersecting infrared lights. These infrared lights intersect within the keyboard operation area, forming a dense infrared light network for detecting the movement of the keys. Each infrared emitting tube is provided with a radiation angle, and only infrared receiving tubes within this radiation angle can receive the infrared light emitted by the corresponding infrared emitting tube.

When a key on the keyboard is pressed, the light-blocking cylinder at the bottom of the key moves downward and intrudes into the infrared light network. As the light-blocking cylinder moves, it blocks the infrared light passing through the key. Each infrared receiving tube detects changes in the signal strength of the infrared light emitted by the corresponding infrared emitting tube. If the signal strength change exceeds a preset threshold, the system records the serial number of the infrared light that cause the change, thereby obtaining the blocked light path combination corresponding to the key.

By analyzing the blocked light path combination, the system can identify the target key that is pressed. At the same time, based on the signal strength change value of the blocked light path combination, the system can calculate the vertical depth of the light-blocking cylinder intruding into the infrared light network, thereby determining the travel depth of the target key. This embodiment not only detects whether the key is pressed but also measures the press depth of the key, providing users with a richer interactive experience.

Referring to FIG. 3, step S20 includes steps S210 to S230.

Step S210: obtaining signal strength values of all current infrared lights, filtering out infrared lights with signal strength values lower than the preset threshold to obtain the blocked infrared lights.

During the operation of the infrared keyboard, pressing the key blocks part of the infrared light, causing the signal strength received by the corresponding infrared receiving tube to change. The preset threshold is determined during system initialization, which is based on the initial signal strength value received by the infrared receiving tube when the key is not operated, analyzed through multiple sampling cycles, and taken into account factors such as environmental interference. This ensures sensitivity while effectively preventing signal strength fluctuations caused by false touch operations. The preset threshold can also be determined based on expert experience or historical usage data of the keyboard key.

The system periodically collects the signal strength values received by the infrared receiving tube. These signal strength values are converted from analog signals to digital signals through an analog-to-digital conversion circuit and then read by the system. A pre-programmed algorithm in the system compares the signal strength value of each collected infrared light with a preset threshold. Infrared light signals with a signal strength value below the preset threshold are identified as the blocked infrared lights.

Step S220: determining serial numbers of the blocked infrared lights based on a preset infrared light numbering rule.

In this embodiment, in order to accurately distinguish and locate different infrared light signals, the corresponding infrared light signal is determined based on the arrangement of the infrared emitting tube and infrared receiving tube. For example, a unique serial number is assigned to each infrared light signal in a left-to-right and top-to-bottom order. The serial number information of the infrared light is stored in the memory of the system, forming a serial number mapping table of the infrared light. Once the blocked infrared light is identified, the corresponding serial number of each blocked infrared light is quickly queried and determined based on the serial number mapping table of the infrared light.

Step S230: combining the serial numbers of the blocked infrared lights in a same time window to form the blocked light path combination.

The time window refers to a time range during the detection process of the system, configured to determine infrared light signal strength changes resulting from key operations in the same timing. The system detects keyboard key operations through sequentially activating infrared emitting tubes. Specifically, the system predetermines the activation sequence for each infrared emitting tube, and each infrared emitting tube emits infrared light sequentially within the same time window. When some infrared emitting tube is activated, the infrared light emitted by that infrared emitting tube is synchronously received by the corresponding infrared receiving tube within the effective radiation angle range. At the same time, the system simultaneously collects the signal strength values received by each infrared receiving tube within the time window.

In an embodiment, the activation of the infrared emitting tubes is controlled by a pulse width modulation (PWM) signal. The activation time of each infrared emitting tube is very short, allowing for sequential activation through rapid switching.

In an embodiment, the activation sequence of the infrared emitting tubes is controlled by electronic switches or logic circuits, activating each infrared emitting tube according to a predetermined pattern or sequence.

It should be noted that all infrared emitting tubes are activated sequentially in a preset order, forming a detection cycle. The system assigns a unique timestamp to each detection cycle to identify and distinguish infrared light data from different detection cycles. In this embodiment, a detection cycle can be treated as a time window. Within each time window, if the system detects that the signal strength value received by the infrared receiving tube is below the preset threshold, the corresponding infrared light is determined to be blocked. Since these blocked infrared lights are detected within the same time window, they are considered to be blocked by the same key operation. At this point, the system obtains the serial numbers of all blocked infrared lights determined within the time window. These serial numbers are then sorted according to a rule (for example, from smallest to largest) to form a blocked light path combination corresponding to the key. Finally, the system searches for a pre-stored mapping relationship table between keys and blocked light path combinations to match the blocked light path combination with the preset blocked light path combination corresponding to the known key, thereby determining the specific location of the key.

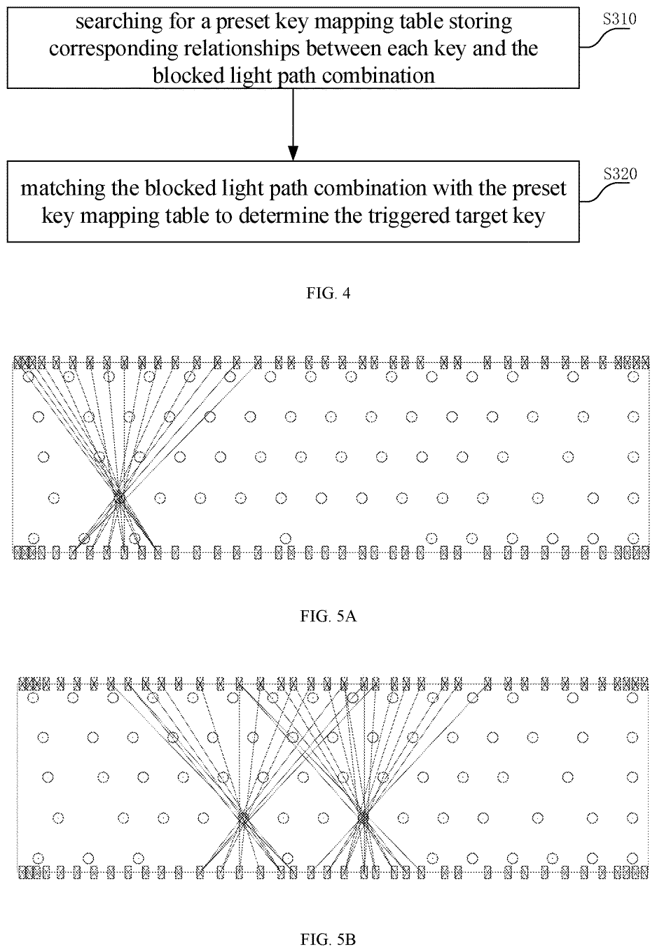

Referring to FIG. 4, step S30 includes steps S310-S320.

Step S310: searching for a preset key mapping table storing corresponding relationships between each key and the blocked light path combination.

Step S320: matching the blocked light path combination with the preset key mapping table to determine the triggered target key.

The key mapping table stores the corresponding relationship between each key and the blocked light path combination. In this embodiment, since the positions of the keyboard keys are fixed, the system pre-establishes a mapping relationship table between keys and blocked light path combinations, with each key pre-associated with a specific blocked light path combination. Specifically, the serial number of each infrared light is determined in advance based on the arrangement of the infrared emitting tube and the infrared receiving tube. By pressing the keyboard keys one by one, the serial numbers of the blocked infrared lights in the infrared light network when each key is pressed is recorded. The serial numbers of the blocked infrared lights corresponding to all keys are then recorded and stored in the key mapping table to maintain the corresponding relationship between each key and the corresponding serial number of the blocked infrared light.

Once the system obtains the current blocked light path combination, it retrieves the key mapping table from the storage area and traverses the key mapping table to search for a blocked light path combination that matches the detected current blocked light path combination. Once a match is found, the triggered target key is determined.

In an embodiment, step S320 may further include steps S3210 to S3230.

Step S3210: in response to that there is no single target key that fully matches the blocked light path combination in the key mapping table, searching for all candidate keys that partially match the blocked light path combination in the key mapping table.

In this embodiment, the key mapping table stores a unique corresponding relationship between each key and the blocked light path combination. However, when multiple keys are pressed simultaneously, the detected blocked light path combination may not fully match the preset blocked light path corresponding to a single key in the mapping table. In this case, the system searches the mapping table for all candidate keys that partially match the detected current blocked light path combination. A partial match means that a portion of the detected current blocked light path combination is overlapped with the preset blocked light path combination corresponding to the key in the key mapping table.

Step S3220: based on a preset blocked light path combination corresponding to the candidate keys, determining whether there exists a key combination that fully matches the blocked light path combination after merging with the preset blocked light path combination corresponding to the key combination.

Step S3230: in response to that there exists the key combination that fully matches the blocked light path combination after merging with the preset blocked light path combination corresponding to the key combination, determining the key combination as the triggered target key.

After finding all partially matching candidate keys, the system further determines whether there is a key combination such that the preset blocked light path combination corresponding to these candidate keys, after merging, fully matches the detected blocked light path combination. Specifically, the system permutes and combines these candidate keys and merges the preset blocked light path combinations corresponding to each of these combinations (taking the union and removing duplicate light paths). The results are then compared with the detected current blocked light path combination. If the merged blocked light path combination for a key combination is identical to the detected current blocked light path combination, this key combination is the currently triggered target key. The system then triggers the corresponding action based on the determined target key.

In this embodiment, the system uses a key mapping table to handle the recognition of single and multiple key presses. Specifically, the mapping relationship table stores the basic mapping relationship for the preset blocked light path combination of each individual key. Therefore, based on this basic mapping relationship, combinatorial logical mapping can be implemented to represent the association among the blocked light path combinations of different keys, including the key combinations that can be triggered simultaneously and the changing characteristics of the blocked light path combinations corresponding to each key combination.

Specifically, when the system detects the current blocked light path combination, it performs a multi-stage determination process: checking whether the basic mapping relationship of the blocked light path combination for a single key is matched; if no fully match is found, performing combinational logic identification, analyzing the distribution characteristics of the serial numbers in the blocked light path combination, decomposing the blocked light path combination into the intersection of multiple blocked light path combinations corresponding to single keys, and obtaining candidate keys; and verifying whether there is a key combination among these candidate keys such that the union of the blocked light path combinations corresponding to this key combination is exactly the same as the current blocked light path combination.

In an embodiment, after pressing key A, the corresponding blocked light path combination is 1, 3, and 5; while after pressing key B, the corresponding blocked light path combination is 8, 9, and 11. If the system detects that the blocked light path combination for a key is 1, 3, 5, 8, 9, and 11, it can be inferred that key A and key B are pressed simultaneously.

In an embodiment, step S3230 may further include steps S32310 to S32320.

Step S32310: calculating a blocking priority of each key in the key combination based on an amount of the blocked infrared lights in the preset blocked light path combination corresponding to each key in the key combination.

S32320: determining a triggering order of each key in the key combination in a descending order of the blocking priority.

In this embodiment, when it is determined that the current key trigger operation is triggered by multiple keys simultaneously, the system needs to further determine the triggering order within the key combination. Therefore, the system calculates the blocking priority of each candidate key. The blocking priority reflects the order of each key in each key combination under the current blocking condition. The blocking priority is calculated based on the ratio of the actual amount of blocked infrared lights in the preset blocked light path combination corresponding to each key to the total amount of infrared light in the preset blocked light path combination corresponding to that key.

After determining the blocking priority of each key in the key combination, the system sorts the keys from highest to lowest based on these priorities to determine the key triggering order. Keys with higher priorities are considered the first keys pressed by the user and are therefore triggered first. This allows the system to more accurately identify key pressing of the user in scenarios where multiple keys are pressed simultaneously, improving input accuracy.

In an embodiment, in order to realize the implementation process of the detection method for keyboard key, please refer to FIG. 5A. FIG. 5A provides a schematic diagram of the blocked infrared light network when the key is pressed.

Specifically, in the keyboard operation area, when a single key is pressed, the light-blocking cylinder at the bottom of the key moves downward and intrudes into the infrared light network, blocking the portion of infrared light passing through the bottom of the key. As shown in FIG. 5A, a specific group of infrared lights in the infrared light network formed by the infrared emitting tubes and infrared receiving tubes opposite to the infrared emitting tubes is blocked by the key action. The system uses a preset infrared light numbering rule to obtain the serial number of each blocked infrared light in the group, and combines all corresponding infrared light serial numbers in this group to form a blocked light path combination corresponding to the key.

In an embodiment, in order to realize the implementation process of the detection method for keyboard key, please refer to FIG. 5B, which provides a schematic diagram of the blocked infrared light network when two keys are pressed.

Specifically, in the keyboard operation area, when two keys are pressed simultaneously, the light-blocking cylinders at the bottom of the two keys move downward simultaneously and intrude into the infrared light network, which blocks more infrared light. As shown in FIG. 5B, two groups of infrared light passing through the two keys are blocked. During key detection, the system also determines the serial numbers of the blocked infrared lights in these two groups according to the infrared light numbering rule and combines them to form a blocked light path combination corresponding to the two keys.

It should be noted that when two or more keys are pressed simultaneously, some infrared light may be blocked repeatedly. In order to ensure the accuracy of the blocked light path combination, the system integrates the serial numbers of the blocked infrared lights and removes duplicate serial numbers to obtain a blocked light path combination without duplicate serial numbers.

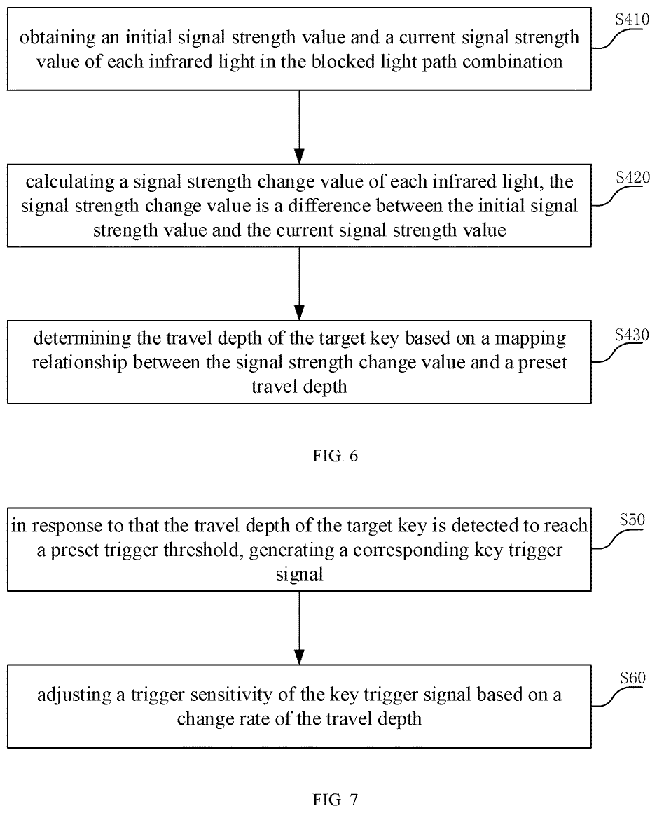

Referring to FIG. 6, step S40 further includes steps S410 to S430.

Step S410: obtaining an initial signal strength value and a current signal strength value of each infrared light in the blocked light path combination.

The initial signal strength value refers to the signal strength of the corresponding infrared light received by the infrared receiving tube when no key is pressed. During the design phase of the keyboard, the system samples the signal strength of each infrared light multiple times and determines a stable initial value. The current signal strength value is the signal strength of the infrared light received by the infrared receiving tube and collected in real time by the system when a key operation is detected and a blocked light path combination is formed. When the system detects the key operation, it immediately initiates signal acquisition, converts the analog signal received by the infrared receiving tube into a digital signal, and obtains the current signal strength value corresponding to each infrared light within the blocked light path combination associated with the current key operation.

Based on the blocked light path combination associated with the current key operation, the system determines the initial signal strength value of the corresponding infrared light based on the serial number of each infrared light within the current blocked light path combination, and simultaneously collects the current signal strength value.

Step S420: calculating a signal strength change value of each infrared light, the signal strength change value is a difference between the initial signal strength value and the current signal strength value.

After obtaining the initial signal strength value and the current signal strength value for each infrared light path in the blocked light path combination, the system performs a subtraction operation to calculate the signal strength change value for each infrared light path. The signal strength change value intuitively reflects the change in signal strength received by the infrared receiving tube due to the light-blocking cylinder blocking the infrared light after the key is pressed. A larger signal strength change value indicates a greater blocking degree of the light-blocking cylinder at the bottom of the key to the infrared light, which means the key is pressed deeper.

Step S430: determining the travel depth of the target key based on a mapping relationship between the signal strength change value and a preset travel depth.

The preset travel depth mapping relationship is established during the design and testing phase of the keyboard. By testing keys at different travel depths and recording the infrared light signal strength change value corresponding to each travel depth, the corresponding relationship between signal strength change value and travel depth is determined. After calculating the signal strength change value for each infrared light path, the system uses the average of these signal strength change values as the strength change value corresponding to the blocked light path combination for the current key operation. The system then searches for and matches the signal strength change value corresponding to the blocked light path combination within the preset relationship model or the travel depth mapping relationship.

It should be noted that the corresponding relationship between the signal strength change value corresponding to the blocked light path combination and the travel depth can be established by simulating key pressing habits of different users and collecting a large amount of key data, including the force, speed, and duration of key pressings, as well as the signal strength change detected by the infrared receiving tube. This key data is then processed using statistical analysis and machine learning algorithms to identify the correlation between travel depth and the signal strength change value.

In an embodiment, a relationship model between the signal strength change and the travel depth of the key can be established, or a travel depth mapping relationship between the strength change and the travel depth of the key can be established.

It should be noted that if the signal strength change does not completely correspond to the value in the preset relationship model or the travel depth mapping relationship, a method such as linear interpolation can be used to estimate the corresponding travel depth by calculating adjacent data points, ultimately determining the travel depth of the target key.

Referring to FIG. 7, the detection method for keyboard key of the present application further includes steps S50-S60 after step S40.

Step S50: in response to that the travel depth of the target key is detected to reach a preset trigger threshold, generating a corresponding key trigger signal.

The preset trigger threshold is a key parameter based on the design purpose of the keyboard and operating habits of the user. It indicates the travel depth which the key must reach to be considered a valid trigger. Travel depth requirements for key triggering are different among keyboards designed for different purposes, such as gaming keyboards and office keyboards. The gaming keyboard may require a more sensitive trigger, that is, the trigger threshold is relatively low to ensure quick response to game actions. Meanwhile, the work keyboard may prioritize stability, so the trigger threshold may be slightly higher. Furthermore, different users may have different keyboard preferences. Some prefer a light touch for a response, while others prioritize firm pressure. This difference can lead to individual changes in the travel depth of the key and the signal strength change value of the blocked light path combination corresponding to each key. Therefore, in order to accommodate preferences of different user, key trigger conditions can be configured, such as by adjusting the key trigger position, to provide a different keyboard experience and meet the personalized needs of different users.

It should be noted that the higher the trigger threshold, the deeper the travel depth required to press the key.

In an embodiment, users can customize the trigger threshold for the travel depth of the key to achieve a more personalized experience. This can be achieved through key combinations or software settings. Through the software interface, users can access a configuration menu that provides options for adjusting the trigger threshold to meet their individual requirements for response speed and accuracy of the keyboard. Furthermore, these settings can be quickly accessed and modified through specific key combinations, making the entire adjustment process more intuitive and convenient.

In an embodiment, the vertical depth of the key is divided into three regions, and the trigger threshold of each region is different. The shallow press region is set to a travel depth of 1-2 mm; the standard press region is set to a travel depth of 2-3 mm; and the deep press region is set to a travel depth exceeding 3 mm. This division enables the system to provide different trigger thresholds, achieving more accurate key detection, enhancing the adaptability of the keyboard for different user habits, and improving the overall user experience.

Step S60: adjusting a trigger sensitivity of the key trigger signal based on a change rate of the travel depth.

The change rate of travel depth indicates the speed at which the key is pressed. The pressing speed of the key varies due to different habits of different users. In order to ensure stable and accurate response of the keyboard at various operation speeds, the system adjusts the trigger sensitivity based on the change rate of the travel depth.

Specifically, the system continuously monitors the travel depth data of the target key within a preset time interval, using the formula:

$$change rate of the travel depth = \frac{( current travel depth - previous travel depth )}{preset time interval}$$

Furthermore, the trigger sensitivity is adjusted as follows: when the change rate of the travel depth is detected to exceed the first rate threshold, it indicates that the user presses the key relatively fast. The system lowers the trigger threshold to prevent the key from being triggered due to incomplete key pressings. Therefore, in this case, the key only needs to be pressed to a relatively shallow depth to reach the new lower trigger threshold and be effectively triggered.

When the change rate of the travel depth is detected to be lower than the second rate threshold, it indicates that the user presses the key relatively slowly. The system raises the trigger threshold to prevent false key touches.

In an embodiment, in a game scenario, during intense team battle, players may need to quickly press multiple skill keys to unleash combos. In this scenario, the player presses the key extremely fast, and the change rate of the travel depth may exceed the first rate threshold. If the system does not adjust the trigger threshold, due to the extremely short time it takes for the player to press the key, some keys may not reach the original trigger threshold in time, resulting in skill unrelease, affecting game play and the overall flow of the battle. To prevent this, the system automatically lowers the trigger threshold. For example, the original trigger threshold is set to a press depth of 2 mm, after the system lowers the threshold, the press depth of only 1.5 mm may be required for the key to be effectively triggered. This ensures that the rapid key pressings of the player are promptly responded to, allowing players to smoothly unleash skills in the game and enhancing the gaming experience.

In an embodiment, in office scenarios, such as copywriting, users typically type while thinking. At this time, their typing speed is relatively slow, and the change rate of the travel depth may be lower than the second rate threshold. If the trigger threshold is low, false touches may occur. For example, a key input may be triggered by a finger lightly resting on the key, resulting in incorrect character input. To prevent such false touches, the system automatically raises the trigger threshold. For example, if the original trigger threshold is set to a press depth of 1.5 mm, the system may raise the threshold to the press depth of 2 mm. This means that the user needs to press the key harder to trigger, thereby reducing the probability of false touches and improving the accuracy and efficiency of office typing.

In an embodiment, step S50 may be followed by steps S51 to S53.

Step S51: detecting changes in infrared light signal strength in an adjacent area of the target key.

In actual keyboard operation, users may accidentally touch the area surrounding the target key, causing changes in the infrared light signal strength in the adjacent area. To identify this situation, after detecting that the travel depth of the target key has reached the trigger threshold and generating a key trigger signal, the system further detects changes in infrared light signal strength in the adjacent area of the target key.

The system predefines the range of adjacent area of each key, determines the corresponding light path to be detected, and periodically collects signal strength values received by the infrared receiving tubes in these adjacent areas using the same signal strength detection method as for detecting the target key.

Step S52: in response to that a concomitant signal change exists in the adjacent area of the target key, determining whether a false touch operation occurs.

It should be noted that the concomitant signal change refers to a non-actively triggered, associated signal change in the infrared light in the adjacent area when the target key is pressed.

Typically, the concomitant signal change has the following characteristics: it occurs synchronously with the primary key pressing, with a time deviation less than the preset deviation threshold; or the attenuation of the signal strength is less than the preset attenuation value for the area corresponding to the target key; or the concomitant signal change occurs in a blocked area that does not conform to the area outline corresponding to the position of the preset key.

When a change in the infrared light signal strength is detected in the adjacent areas of the target key, the system analyzes it based on pre-defined rules. For example, if the signal strength change pattern in the adjacent areas differs significantly from that of the normal key operation, or if multiple infrared light signal strength changes occur simultaneously and significantly in adjacent areas, and do not conform to the signal change characteristics of adjacent areas during normal key operation, the system will determine that a false touch operation may have occurred.

In an embodiment, during the normal key operation, signal strength changes are typically concentrated in the light path corresponding to the target key, with large changing amplitude and a specific order. For example, when a user presses the space bar, signal strength changes mainly occur in the light path corresponding to the space bar, and these changes occur gradually. However, during a false touch operation, signal strength changes in adjacent light paths are often smaller and more dispersed, and may even occur simultaneously in multiple light paths. For example, if the edge of a user's finger accidentally blocks adjacent light paths while pressing the space bar, the signal strength changes in these light paths may be only about 30% of the change in the target key light path. These changes occur almost simultaneously, with very small timing deviations, typically within 1-2 milliseconds.

Furthermore, false touches can cause signal strength changes to occur in areas that don't conform to the layout of the key. For example, under normal circumstances, when pressing the space bar, only the light path corresponding to the space bar is blocked. However, if a false touch causes the edge of the finger to block the light paths above or below the space bar, the signal strength changes in these light paths will not conform to the regional distribution characteristics of normal key operations.

Step S53: in response to that the false touch operation occurs, suppressing signal output in the adjacent area of the target key.

When the system determines that the adjacent area of the target key in the current operation is a false touch, to avoid outputting an erroneous key signal to the computer system and causing an erroneous operation, the system suppresses the signal output from the adjacent area of the target key and only outputs the signal corresponding to the target key, thereby executing the corresponding operation.

The present application provides a detection device for keyboard key, including: at least one processor and a memory communicated with the at least one processor. The memory stores instructions executable by the at least one processor, and the instructions are executed by the at least one processor to enable the at least one processor to perform the detection method for keyboard key.

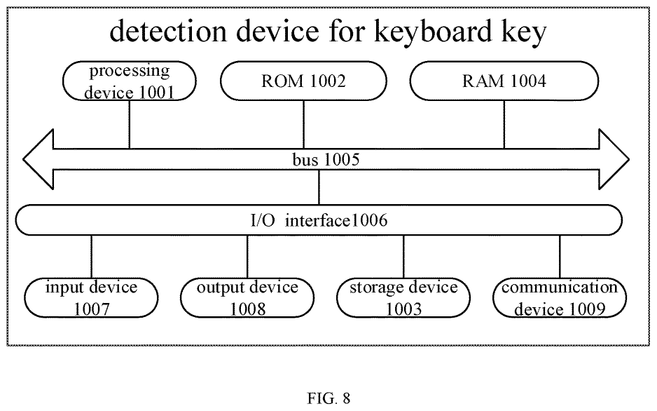

Referring to FIG. 8 which shows a schematic structural diagram of the detection device for keyboard key suitable for implementing the embodiment of the present application. The detection device for keyboard key in the present application may include various hardware and software components for implementing the detection method for keyboard key. The detection device for keyboard key shown in FIG. 8 is merely an example and should not limit the functionality or scope of the present application. As shown in FIG. 8, the detection device for keyboard key may include a processing device 1001 (e.g., a central processing unit (CPU) or graphics processing unit (GPU)). This processing device can perform various appropriate actions and processes based on programs stored in a read-only memory (ROM) 1002 or programs loaded from a storage device 1003 into a random access memory (RAM) 1004. The RAM 1004 also stores various programs and data required for the operation of the detection device for keyboard key. The processing device 1001, the ROM 1002, and the RAM 1004 are interconnected via a bus 1005. An input/output (I/O) interface 1006 is also connected to the bus. Typically, the following systems may be connected to the I/O interface 1006: the input device 1007, such as a touchscreen, touchpad, or keyboard; the output device 1008, such as a liquid crystal display (LCD), speaker, or vibrator; the storage device 1003, such as a magnetic tape or hard disk; and the communication device 1009. The communication device 1009 can allow the detection device for keyboard key to communicate wirelessly or wired with other device to exchange data. Although the figure shows detection device for keyboard key with various systems, it should be understood that implementation or presence of all the illustrated systems is not required. More or fewer systems may be implemented.

In particular, according to the embodiments disclosed herein, the processes described above with reference to the flowcharts can be implemented as computer software programs. For example, the embodiments disclosed herein include a computer program product including a computer program embodied on a computer-readable medium, the computer program containing program code for executing the methods illustrated in the flowcharts. In such embodiments, the computer program can be downloaded and installed from a network via a communication device, or installed from the storage device 1003 or the read-only memory 1002. When executed by the processing device 1001, the computer program performs the functions defined in the methods of the embodiments disclosed herein.

The detection device for keyboard key provided herein, employing the detection method for keyboard key described in the above embodiments, can address the technical issue of the high cost of depth detection of the keyboard key. Compared to the related art, the detection device for keyboard key provided in the present application achieves the same beneficial effects as the detection method for keyboard key provided in the aforementioned embodiment. Other technical features of this detection device for keyboard key are the same as those disclosed in the aforementioned embodiment and are not further elaborated here.

It should be understood that the various components disclosed in the present application can be implemented using hardware, software, firmware, or a combination thereof. In the description of the aforementioned embodiments, specific features, structures, materials, or characteristics may be combined in any suitable manner in any one or more embodiments or examples.

The foregoing descriptions are merely specific embodiments of the present application, but the scope of the present application is not limited thereto. Any modifications or substitutions readily conceivable by those skilled in the art within the technical scope disclosed in the present application are intended to be covered by the scope of the present application. Therefore, the scope of the present application shall be governed by the scope of the claims.

The present application provides a computer-readable storage medium provided with computer-readable program instructions (i.e., a computer program) stored thereon. The computer-readable program instructions are used to execute the detection method for keyboard key described in the aforementioned embodiment.

The computer-readable storage medium provided herein may be, for example, a USB flash drive, but is not limited to electrical, magnetic, optical, electromagnetic, infrared light, or semiconductor systems, systems, or devices, or any combination thereof. More specific examples of computer-readable storage media may include, but are not limited to, an electrical connection having one or more wires, a portable computer disk, a hard disk, random access memory (RAM), read-only memory (ROM), erasable programmable read-only memory (EPROM or flash memory), optical fiber, a portable compact disk read-only memory (CD-ROM), an optical storage device, a magnetic storage device, or any suitable combination thereof. In this embodiment, the computer-readable storage medium may be any tangible medium that contains or stores a program that can be used by or in conjunction with an instruction execution system, system, or device. The program code contained on the computer-readable storage medium may be transmitted using any suitable medium, including, but not limited to, wires, optical cables, radio frequency (RF), etc., or any suitable combination thereof. The computer-readable storage medium may be included in the detection device for keyboard key, or may exist independently and not incorporated into the detection device for keyboard key.

The computer-readable storage medium carries one or more programs. When executed by the detection device for keyboard key, the one or more programs cause the detection device for keyboard key to: detect the signal strength value of the infrared light received by the infrared receiving tube; when the signal strength value is below a preset threshold, identify the blocked infrared lights and generate a blocked light path combination; determine a triggered target key based on the blocked light path combination; and calculate the travel depth of the target key based on the signal strength change value of the blocked light path combination.

The computer program code for performing the operations of the present application may be written in one or more programming languages, or a combination thereof. The programming languages include object-oriented programming languages such as Java, Smalltalk, and C++, as well as conventional procedural programming languages such as C or similar programming languages. The program code may execute entirely on the user's computer, partially on the user's computer, as a stand-alone software package, partially on the user's computer and partially on a remote computer, or entirely on a remote computer or server. In the case of a remote computer, the remote computer may be connected to the user's computer via any type of network, including a local area network (LAN) or a wide area network (WAN), or may be connected to an external computer (e.g., via the Internet using an Internet service provider).

The flowcharts and block diagrams in the accompanying drawings illustrate the architecture, functionality, and operation of possible implementations of the systems, methods, and computer program products according to various embodiments of the present application. In this regard, each block in the flowchart or block diagram may represent a module, program segment, or portion of code, which contains one or more executable instructions for implementing the specified logical function. It should also be noted that in some alternative implementations, the functions noted in the blocks may occur in a different order than indicated in the accompanying drawings. For example, two blocks shown in succession may actually be executed substantially in parallel, or they may sometimes be executed in the opposite order, depending on the functions involved. It should also be noted that each box in the block diagrams and/or flowcharts, and combinations of boxes in the block diagrams and/or flowcharts, can be implemented by a dedicated hardware-based system that performs the specified function or operation, or can be implemented by a combination of dedicated hardware and computer instructions.

The modules described in the embodiments of the present application can be implemented via software or hardware. The module names, in some cases, do not limit the modules themselves.

The readable storage medium provided in the present application is a computer-readable storage medium storing computer-readable program instructions (i.e., a computer program) for executing the aforementioned detection method for keyboard key, which can address the technical issue of high cost of depth detection of the keyboard key. Compared to the related art, the computer-readable storage medium provided in the present application has the same beneficial effects as the detection method for keyboard key provided in the aforementioned embodiments, and are not further elaborated here.

The embodiments of the present application provide a computer program product, including a computer program. When executed by a processor, the computer program implements the steps of the aforementioned detection method for keyboard key.

The computer program product provided in the present application can address the technical issue of high cost of depth detection of the keyboard key. Compared to the related art, the computer program product provided in the present application has the same beneficial effects as the detection method for keyboard key provided in the aforementioned embodiments, and are not further elaborated here.

The above are merely preferred embodiments of the present application and are not intended to limit the scope of the present application. Any equivalent structures or equivalent processes that utilize the contents of this specification and drawings, or that are directly or indirectly applied in other related technical fields, are equally encompassed by the scope of the present application.

It should be noted that, as used herein, the terms “comprise”, “include”, or any other changes thereof are intended to encompass non-exclusive inclusion, such that a process, method, article, or system including a series of elements includes not only those elements but also other elements not explicitly listed, or elements inherent to such process, method, article, or system. Without further limitation, an element specified by the phrase “including a . . . ” does not preclude the presence of other identical elements in the process, method, article, or system including that element.

Through the above description of the embodiments, those skilled in the art will clearly understand that the above-mentioned embodiments and methods can be implemented using software and a necessary general-purpose hardware platform. Hardware implementation is also possible, but in many cases the former is the preferred implementation. The above are only embodiments of the present application and do not limit the scope of the present application. Any equivalent structure or equivalent process transformation made by using the contents of the specification and drawings, or directly or indirectly applied in other related technical fields, are also included in the scope of the present application.

1. A detection method for a keyboard key, applied to an infrared keyboard comprising a keyboard operation area, wherein:
at least one group of opposite sides of the keyboard operation area is provided with an infrared array comprising a plurality of groups of infrared emitting tubes and infrared receiving tubes opposite to the infrared emitting tubes, and an infrared light network composed of a plurality of intersecting infrared lights is formed at the keyboard operation area;
a key is provided at the keyboard operation area, a light-blocking cylinder configured to move vertically with a movement of the key is fixedly provided at a bottom of the key, and the light-blocking cylinder is initially positioned at a preset distance above the infrared light network; and
the detection method for keyboard key comprises:
detecting a signal strength value of an infrared light received by the infrared receiving tube;
in response to that the signal strength value is lower than a preset threshold, identifying blocked infrared lights and generating a blocked light path combination;
determining a triggered target key based on the blocked light path combination; and
calculating a travel depth of the target key based on a signal strength change value of the blocked light path combination;
wherein the determining the triggered target key based on the blocked light path combination comprises:
searching for a preset key mapping table storing corresponding relationships between each key and the blocked light path combination; and
matching the blocked light path combination with the preset key mapping table to determine the triggered target key.

2. The detection method for the keyboard key according to claim 1, wherein the in response to that the signal strength value is lower than the preset threshold, identifying blocked infrared lights and generating the blocked light path combination comprises:
obtaining signal strength values of all current infrared lights, filtering out infrared lights with signal strength values lower than the preset threshold to obtain the blocked infrared lights;
determining serial numbers of the blocked infrared lights based on a preset infrared light numbering rule; and
combining the serial numbers of the blocked infrared lights in a same time window to form the blocked light path combination.

3. (canceled)

4. The detection method for the keyboard key according to claim 1, wherein the matching the blocked light path combination with the preset key mapping table to determine the triggered target key comprises:
in response to that there is no single target key that fully matches the blocked light path combination in the key mapping table, searching for all candidate keys that partially match the blocked light path combination in the key mapping table;
based on a preset blocked light path combination corresponding to the candidate keys, determining whether there exists a key combination that fully matches the blocked light path combination after merging with the preset blocked light path combination corresponding to the key combination; and
in response to that there exists the key combination that fully matches the blocked light path combination after merging with the preset blocked light path combination corresponding to the key combination, determining the key combination as the triggered target key.

5. The detection method for the keyboard key according to claim 4, wherein the in response to that there exists the key combination that fully matches the blocked light path combination after merging with the preset blocked light path combination corresponding to the key combination, determining the key combination as the triggered target key comprises:
calculating a blocking priority of each key in the key combination based on an amount of the blocked infrared lights in the preset blocked light path combination corresponding to each key in the key combination; and
determining a triggering order of each key in the key combination in a descending order of the blocking priority;
wherein the blocking priority is calculated as a ratio of an actual amount of the blocked infrared lights in the preset blocked light path combination corresponding to the key to a total amount of infrared lights in the preset blocked light path combination.

6. The detection method for the keyboard key according to claim 1, wherein the calculating the travel depth of the target key based on the signal strength change value of the blocked light path combination comprises:
obtaining an initial signal strength value and a current signal strength value of each infrared light in the blocked light path combination;
calculating a signal strength change value of each infrared light, wherein the signal strength change value is a difference between the initial signal strength value and the current signal strength value; and
determining the travel depth of the target key based on a mapping relationship between the signal strength change value and a preset travel depth.

7. The detection method for the keyboard key according to claim 1, wherein after calculating the travel depth of the target key based on the signal strength change value of the blocked light path combination, the method further comprises:
in response to that the travel depth of the target key is detected to reach a preset trigger threshold, generating a corresponding key trigger signal; and
adjusting a trigger sensitivity of the key trigger signal based on a change rate of the travel depth;
wherein the trigger sensitivity is adjusted by:
lowering the trigger threshold in response to that the change rate of the travel depth is detected to exceed a first rate threshold; and
raising the trigger threshold in response to that the change rate of the travel depth is detected to be lower than a second rate threshold.

8. The detection method for the keyboard key according to claim 7, wherein after the in response to that the travel depth of the target key is detected to reach the preset trigger threshold, generating the corresponding key trigger signal, the method further comprises:
detecting changes in infrared light signal strength in an adjacent area of the target key;
in response to that a concomitant signal change exists in the adjacent area of the target key, determining whether a false touch operation occurs; and
in response to that the false touch operation occurs, suppressing signal output in the adjacent area of the target key.

9. A detection device for a keyboard key, comprising: a memory, a processor, and a computer program stored in the memory and executable on the processor, wherein the computer program is configured to implement steps of the detection method for the keyboard key according to claim 1.

10. A non-transitory computer-readable storage medium, storing a computer program configured to implement steps of the detection method for the keyboard key according to claim 1 when executed by a processor.
